(19) United States
(12) Patent Application Publication
(10) Pub. No.: US 2009/0072360 A1
(43) Pub. Date: Mar. 19, 2009

(54) Molded semiconductor device including IC-chip covered with conductor member

(75) Inventor: Kazuhiko Koga, Toyohashi-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/230,728

(22) Filed: Sep. 4, 2008

(30) Foreign Application Priority Data
Sep. 18, 2007 (JP) 2007-240907

(51) Int. Cl. H01L 23/495

(52) U.S. Cl. 257/669; 257/E23.031

(57) ABSTRACT

A semiconductor device according to the present invention includes a conductor member, an IC-chip and leads, all molded together with a resin mold. The conductor member is composed of a base portion on which the IC-chip is mounted, a cover portion for covering a functioning surface of the IC-chip, and a bent portion connecting the cover portion to the base portion. The base portion includes a lead portion that is grounded. The cover portion and the base portion are positioned substantially in parallel to each other, and the IC-chip is disposed in an inner space between the cover portion and the base portion. The lead portion to be grounded and the leads electrically connected to the IC-chip extend out of the resin mold. Since the IC-hip is disposed in the inner space of the conductor member that is grounded, the IC-chip is protected from the electromagnetic noises and from electrostatic charges otherwise accumulated in the resin mold.

### CROSS-REFERENCE TO RELATED APPLICATION

This application is based upon and claims benefit of priority of Japanese Patent Application No. 2007-240907 filed on Sep. 18, 2007, the content of which is incorporated herein by reference.

### BACKGROUND OF THE INVENTION

1. Field of the Invention

The present invention relates to a molded semiconductor device including an integrated circuit chip (referred to as an IC-chip).

2. Description of Related Art

An example of a semiconductor device having an IC-chip molded with a resin material is disclosed in JP-B2-2515324. In this device, an IC-chip forming electronic circuits is mounted on a base having a lead portion. The IC-chip is connected to the base with adhesive. The semiconductor device includes leads for electrically connecting the IC-chip to outside circuits. The IC-chip is connected to leads through bonding wires. The IC-chip mounted on the base and all the leads are integrally molded with a resin material. Thus, the IC-chip is hermetically protected from the environment.

However, an functioning surface of the IC-chip may be affected by electromagnetic noises although it is covered with a resin mold. In addition, the resin mold is easily charged electrostatically because the resin mold is made of a dielectric material. When the resin mold is charged, an electrostatic field may be generated at a boundary between the IC-ship and the resin mold. There is a possibility that the IC-chip malfunctions due to the noises and the electrostatic charges. To avoid these problems, it is possible to cover and shield the semiconductor device entirely with a conductive material. However, the semiconductor device becomes bulky and its structure becomes complex if the device is entirely covered with the conductive material.

### SUMMARY OF THE INVENTION

The present invention has been made in view of the above-mentioned problems, and an object of the present invention is to provide an improved semiconductor device which is intercepted from outside noises and electrostatic charges to thereby secure reliable operation.

The semiconductor device of the present invention includes a conductor member, an IC-chip and leads electrically connected to the IC-chip. All of these components are molded together with resin so that a lead portion extending from the conductor member and the leads connected to the IC-ship extend from the resin mold. The conductor member is composed of a cover portion, abase portion having a lead portion extending therefrom and a bent portion connecting the cover portion and the base portion.

The IC-chip is mounted on the base portion, and the cover portion is positioned to cover a functioning surface of the IC-chip by bending the bending portion. The cover portion and the base portion are positioned substantially in parallel to each other, and the IC-chip is disposed in a space between the cover portion and the base portion. An open end of the cover portion is connected to the base portion by a claw portion extending from either the cover portion or the base portion. The conductor member, the IC-chip and the leads are connected together by a resin mold so that the lead portion and the leads extend out of the resin mold. The lead portion extending from the base portion is grounded.

The cover portion covering the functioning surface of the IC-chip is grounded through the lead portion, and the resin mold is grounded through the conductor member. Therefore, the functioning surface of the IC-chip is intercepted from electromagnetic waves, and electrostatic charges accumulating in the resin mold is discharged through the lead portion that is grounded. Thus, the semiconductor device is prevented from malfunctions caused by electromagnetic noises and electrostatic charges.

The structure of the conductor member can be variously modified. For example, the cover portion and the base portion may be formed separately, and they may be connected by welding. Alternatively, the separate cover portion may be electrically connected to the lead portion through a bonding wire. The cover member may be pasted on the functioning surface of the IC-chip. The conductor member may be formed in a cup-shape or a U-shape. The cover portion and the bent portion may be positioned outside of the resin mold. One or more windows may be formed in the bent portion to reduce the spring-back action of the bent portion.

According to the present invention, the semiconductor device is protected form the electromagnetic noises and electrostatic charges by providing the simple and inexpensive conductor member. Other objects and features of the present invention will become more readily apparent from a better understanding of the preferred embodiments described below with reference to the following drawings.

### BRIEF DESCRIPTION OF THE DRAWINGS

FIG. 1A is a plan view showing a semiconductor device molded with resin (the resin is removed for showing an inside structure in all of the following drawings similar to FIG. 1A) as a first embodiment of the present invention;

FIG. 1B is a cross-sectional view showing the semiconductor device along line IB-IB shown in FIG. 1A;

FIGS. 2A-2D are drawings showing a process of manufacturing the semiconductor device;

FIG. 3A is a plan view showing a semiconductor device molded with resin as a second embodiment of the. present invention;

FIG. 3B is a cross-sectional view showing the semiconductor device along line IIIB-IIIB shown in FIG. 3A;

FIG. 3C is a side view showing the semiconductor device, viewed in a direction C shown in FIG. 3A;

FIG. 4A is a plan view showing a semiconductor device molded with resin as a third embodiment of the present invention;

FIG. 4B is a cross-sectional view showing the semiconductor device along line IVB-IVB shown in FIG. 4A;

FIG. 4C is a side view showing the semiconductor device, viewed in a direction C shown in FIG. 4A;

FIG. 5A is a plan view showing a semiconductor device molded with resin as a fourth embodiment of the present invention;

FIG. 5B is a cross-sectional view showing the semiconductor device along line VB-VB shown in FIG. 5A;

FIG. 5C is a side view showing the semiconductor device, viewed in a direction C shown in FIG. 5A;

FIG. 6A is a plan view showing a semiconductor device molded with resin as a fifth embodiment of the present invention;

FIG. 6B is a cross-sectional view showing the semiconductor device along line VIB-VIB shown in FIG. 6A;

FIG. 6C is a side view showing the semiconductor device, viewed in a direction C shown in FIG. 6A;

FIG. 7A is a plan view showing a semiconductor device molded with resin as a sixth embodiment of the present invention;

FIG. 7B is a cross-sectional view showing the semiconductor device along line VIIB-VIIB shown in FIG. 7A;

FIG. 8A is a plan view showing a semiconductor device molded with resin as a seventh embodiment of the present invention;

FIG. 8B is a cross-sectional view showing the semiconductor device along line VIIIB-VIIIB shown in FIG. 8A;

FIGS. 9A-13B show an example of a process for manufacturing the semiconductor device shown in FIG. 8A as the seventh embodiment. Among these drawings, FIG. 9B shows a portion IXB marked in FIG. 9A in an enlarged scale, FIG. 10B is a cross-sectional view along line XB-XB shown in 10A, FIG. 12B is a cross-sectional view along line XIIB-XIIB, and FIG. 13B is a cross-sectional view along line XIIIB-XIIIB shown in FIG. 13A;

FIG. 14A is a plan view showing a semiconductor device molded with resin as an eighth embodiment of the present invention;

FIG. 14B is a cross-sectional view showing the semiconductor device along line XIVB-XIVB shown in FIG. 14A;

FIG. 14C is a side view showing the semiconductor device, viewed in a direction C shown in FIG. 14A;

FIG. 15A is a plan view showing a semiconductor device molded with resin as a ninth embodiment of the present invention;

FIG. 15B is a cross-sectional view showing the semiconductor device along line XVB-XVB shown. in FIG. 15A;

FIG. 16A is a plan view showing a semiconductor device molded with resin as a tenth embodiment of the present invention; and

FIG. 16B is a cross-sectional view showing the semiconductor device along line XVIB-XVIB shown in FIG. 16A.

### DETAILED DESCRIPTION OF THE PREFERRED EMBODIMENTS

Preferred embodiments of the present invention will be described with reference to respective drawings. All the embodiments are generally similar to one another, but each includes some specific features. The similar structures are denoted with the same reference numbers in all of the drawings, and structures specific to each embodiment are denoted with respective reference numbers.

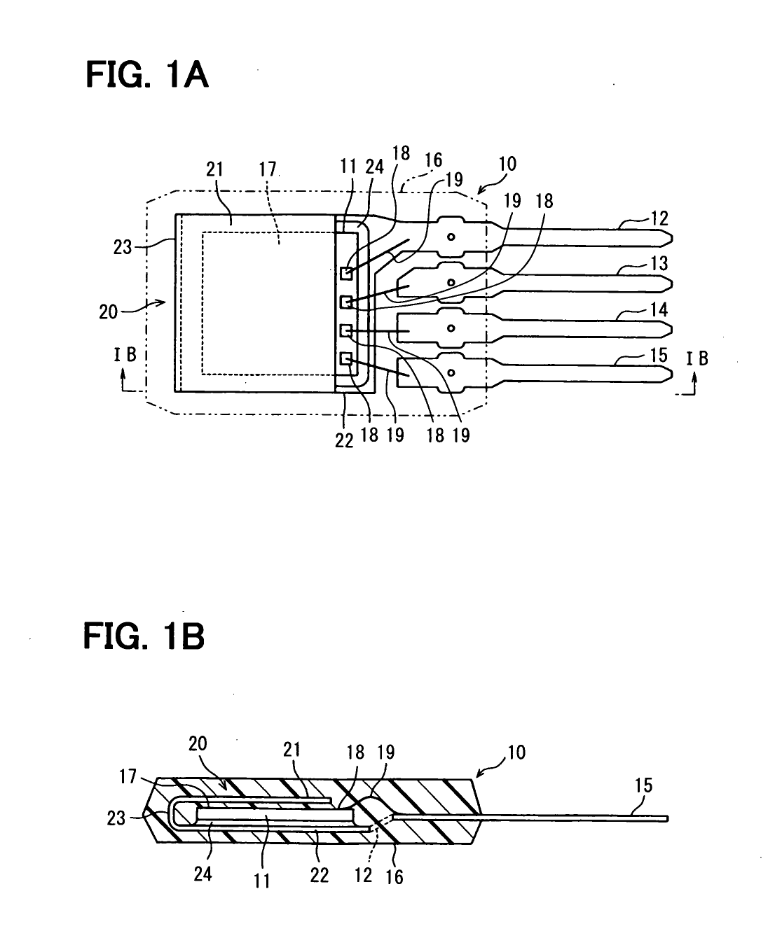

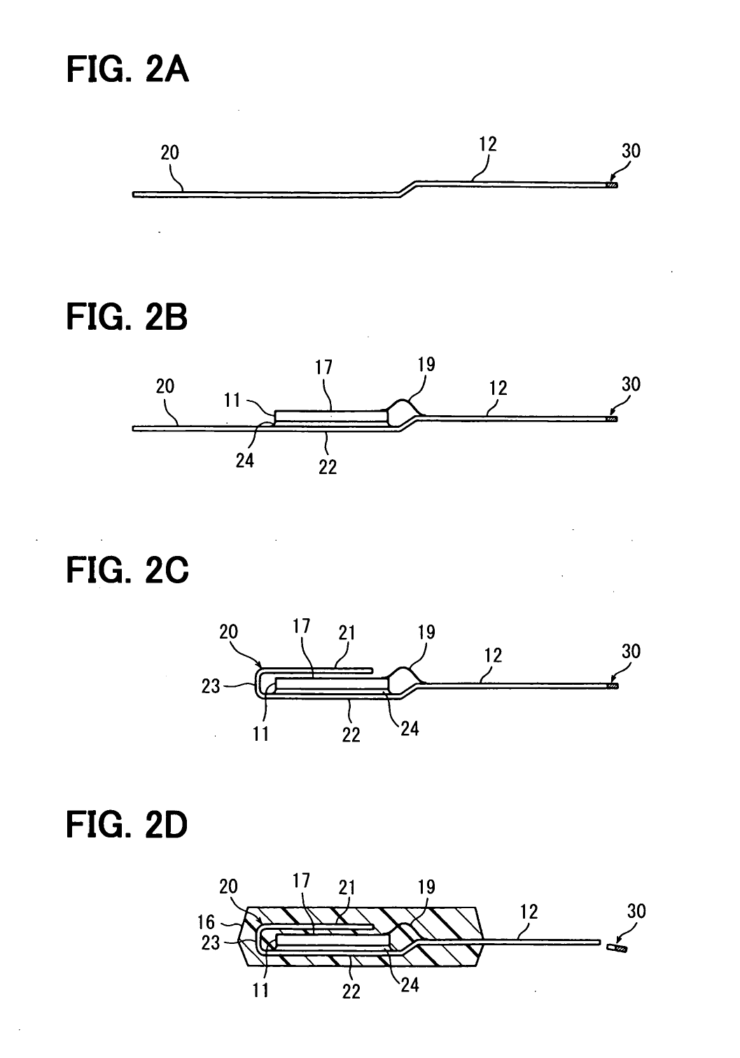

A first embodiment will be described with reference to FIGS. 1A-2D. A semiconductor device 10 is composed of a conductor member 20, an IC-chip 11, leads 13-14 and a resin mold 16 that integrally connects all the components into a single unit. As shown in FIG. 1B, the conductor member 20 includes a cover portion 21, base portion 22 having a lead portion 12 extending from the base portion and a bend portion 23 connecting the base portion 22 to the cover portion 21. The IC-chip 11 is formed on a silicon substrate and has a functioning surface 17 forming a magnetic sensor or the like. The functioning surface 17 includes electronic components such as transistors and capacitors and an integrated circuit including wiring patterns for connecting electronic components. The IC-chip is electrically connected to plural leads 13-15 through bonding pads 18 and bonding wires 19.

The conductor member 20 on which the IC-chip 11 is mounted and leads 13-15 are integrally molded with resin, forming a resin mold 16. The lead portion 12 of the conductor member 20 is connected to an outside ground terminal. The resin mold is made of a resin material such as synthetic resin (such as epoxy resin). All the components forming the semiconductor device 10 are molded together into a single unit, and thereby those components are hermetically protected from the environment.

The conductor member 20 is bent at the bent portion 23, and thereby the cover portion 21 is positioned substantially in parallel to the base portion 22 as shown in FIG. 1B, making an inner space therebetween. The IC-chip 11 is disposed in the inner space and a surface opposite to the functioning surface 17 is connected to the base portion 22 of the conductor member 20 with adhesive 24 such as epoxy resin. The conductor member 20 having the base portion 22, the cover portion 21, the bent portion 23 and the lead portion 12 is integrally formed as a single unit. By grounding the lead portion 12, the entire conductor member 20 is grounded.

A process for manufacturing the semiconductor member 10 will be explained with reference to FIGS. 2A-2D. The conductor member 20 having the lead portion 12 and the leads 13-15 is made from a metallic plate by stamping as shown in FIG. 2A. A lead frame 30 including the conductor member 20 and the leads 13-15 as a single unit is stamped out from the metallic plate. The lead portion 12 extends from the conductor portion 20. The IC-chip 11 is mounted on the base portion 22 of the conductor member 20 as shown in FIG. 2B and pasted on it with adhesive 24. The IC-chip 11 is electrically connected to the lead portion 12 through bonding wires 19. Then, the bent portion 23 is bent to place the cover portion 21 in parallel to the base portion 22 as shown in FIG. 2C. Thus, the cover portion 21 covers the functioning surface 17 of the IC-chip 11. Then, the conductor member 20, the IC-chip 11 and the leads 13-15 are molded together as shown in FIG. 2D, forming the resin mold 16. Finally, the lead frame 30 is cut out from the lead portion 12 and the leads 13-15. Thus, the semiconductor device 10 is completed.

The functioning surface 17 of the IC-chip 11 is covered with the cover portion 11 of the conductor member 20, and the conductor member 20 is grounded through the lead portion 12. Therefore, electrostatic charges accumulated in the resin mold 16 are led out to the ground through the lead portion 12. The outside noises due to electromagnetic waves are intercepted by the cover portion 21 not to reach the functioning surface 17 of the IC-chip 11. Accordingly, the IC-chip 11 is prevented from malfunctioning due to the outside noises or the electrostatic charges.

Since the functioning surface 17 (at least a part) of the IC-chip 11 is covered with the cover portion 21, the semiconductor device 10 can be made compact, compared with a case where an outside of the entire device is covered with a shielding cover. Since the cover portion 21 is made from a single piece of the conductor member 20 by bending the bent portion 23 from the base portion 22, the cover portion 21 is formed without adding an additional component.

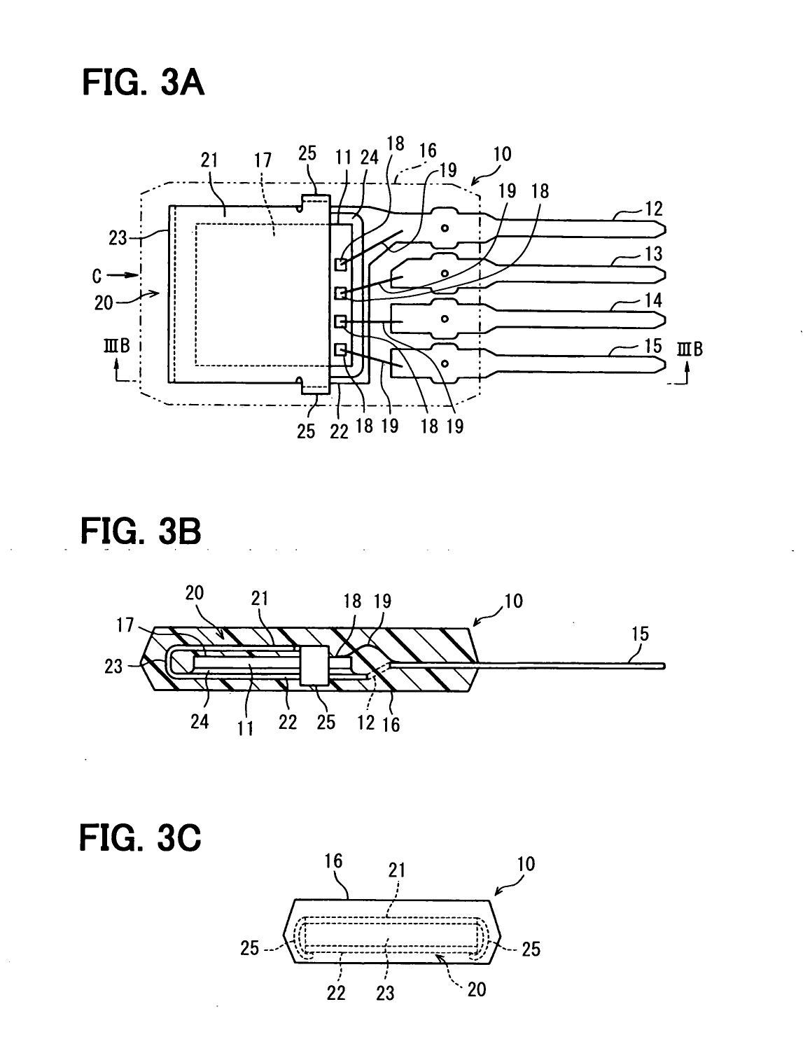

A second embodiment of the present invention is shown in FIGS. 3A-3C. In this embodiment, claws 25 are formed at one end of the cover portion 21, which is opposite to the other end where the bent portion 23 is positioned. The claws 25 are hooked with the base portion 22 as shown in FIGS. 3B and 3C. Thus, the cover portion 21 is correctly positioned relative to the base portion 22 against a spring-back action of the bent portion 23.

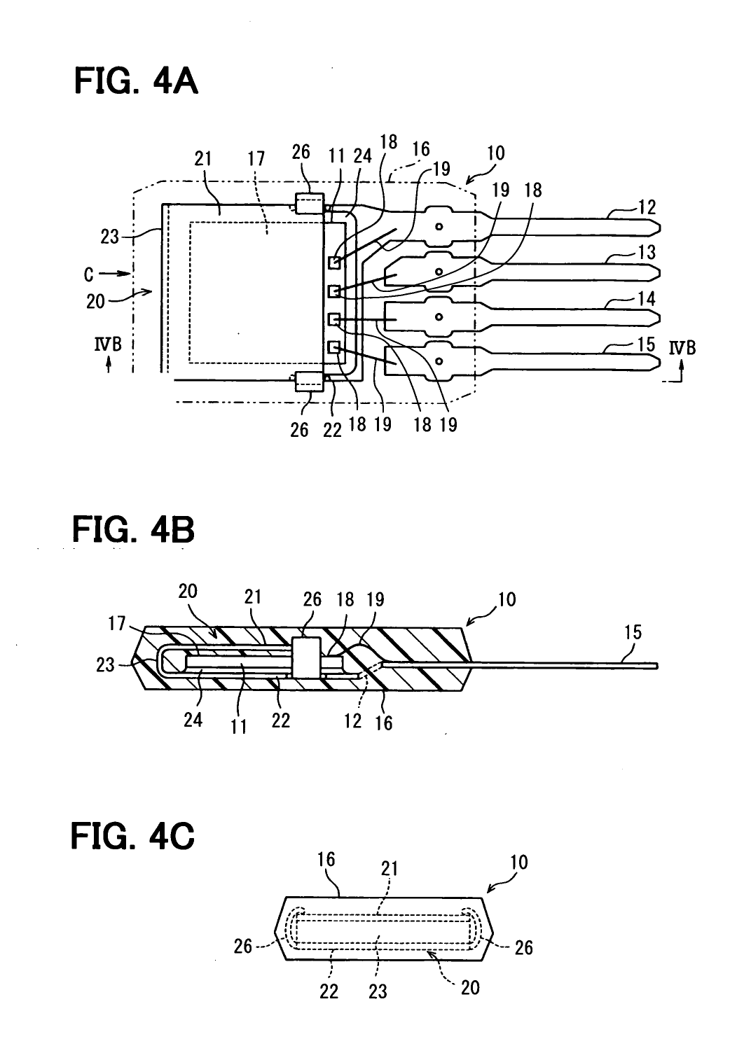

A third embodiment of the present invention is shown in FIGS. 4A-4C. In this embodiment, claws 26 extend from the base portion 22 toward the cover portion 21. The claws 26 are hooked to the cover portion 21 at its one end opposite to the end where the bent portion 23 is connected. The cover portion 21 is correctly positioned relative to the base portion 22 against the spring-back action of the bent portion 23.

In both of the second embodiment and the third embodiment, the cover portion 21 is correctly positioned with respect to the base portion 22 by hooking the claws 25, 26, overcoming a spring-back action of the bent portion 23. In addition, deformation of the conductor member 20 in the molding process is minimized by connecting the cover member 21 to the base member 22 by claws 25, 26.

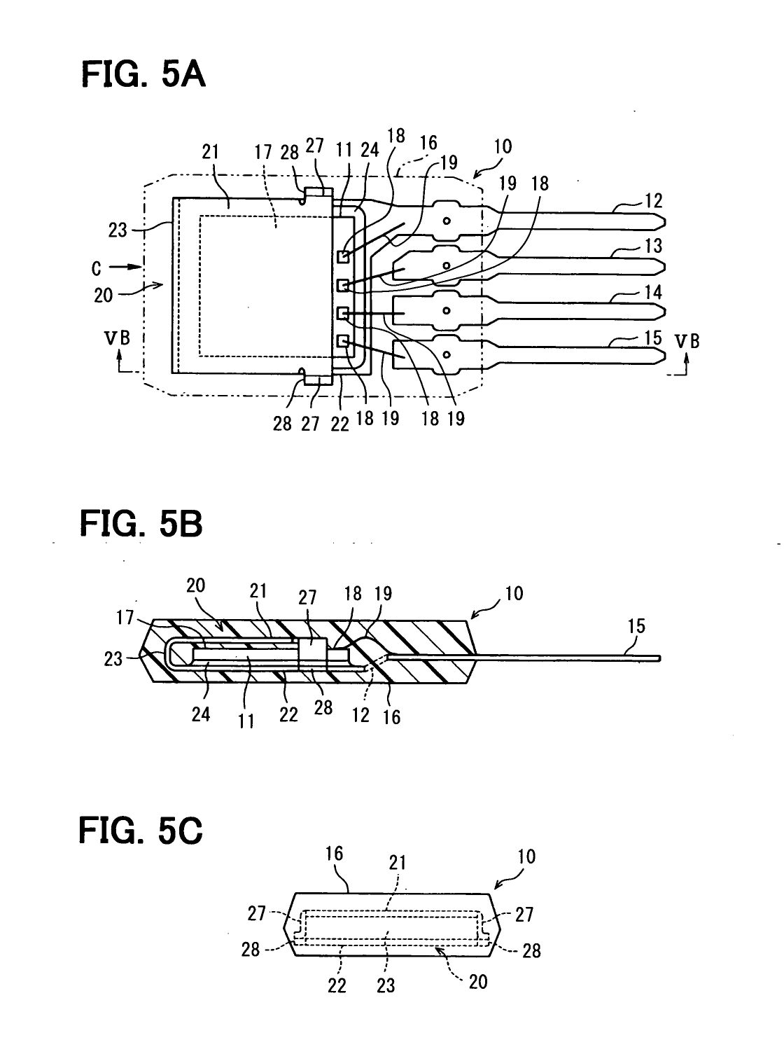

A fourth embodiment of the present invention is shown in FIGS. 5A-5C. In this embodiment, a pair of claws 27 extends from the cover portion 21 toward the base portion 22, and a corresponding pair of fringes 28 is formed on the based portion 22. The claws 27 are connected to the fringes 28 by welding as shown in FIG. 5C. The claws 27 may be extended from the base portion 22 toward the cover portion 21. The deformation of the conductor member 20 is well prevented in this embodiment in the same manner as in the second and the third embodiments.

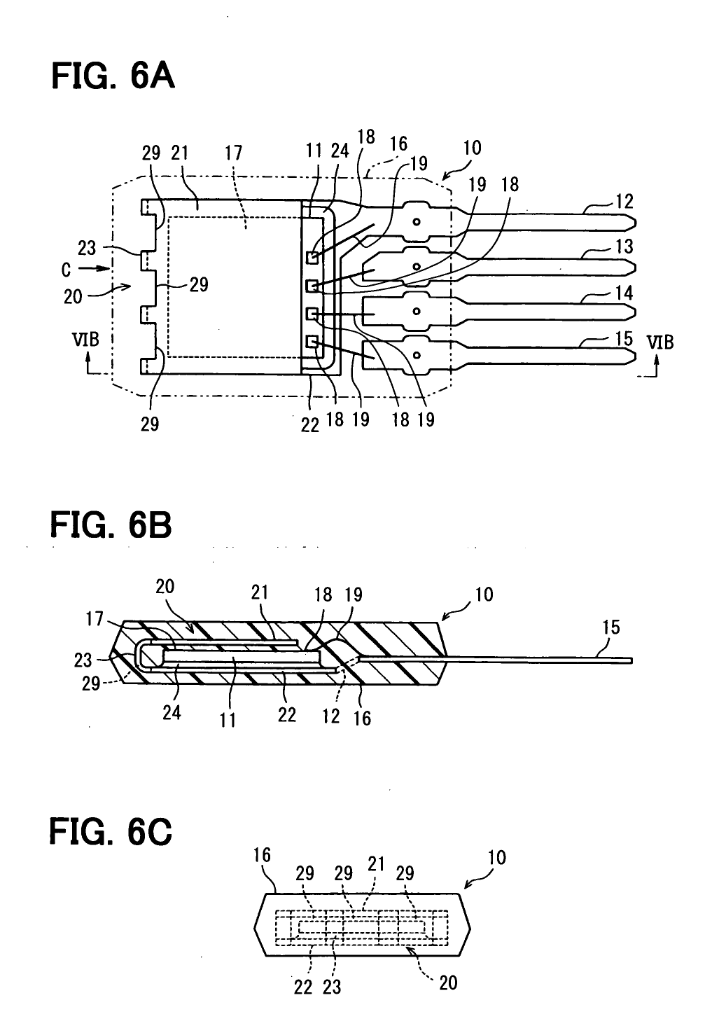

A fifth embodiment of the present invention is shown in FIGS. 6A-6C. In this embodiment, windows 29 are formed in the bent portion 23 to reduce a spring-back reaction of the bent portion when it is bent. In this manner, the bent portion 23 is easily bent, and the cover portion 21 is correctly positioned relative to the base portion 22. The number of windows 29 may be arbitrarily chosen. The windows 29 may be formed on the bent portion 23 in the second to fourth embodiments described above.

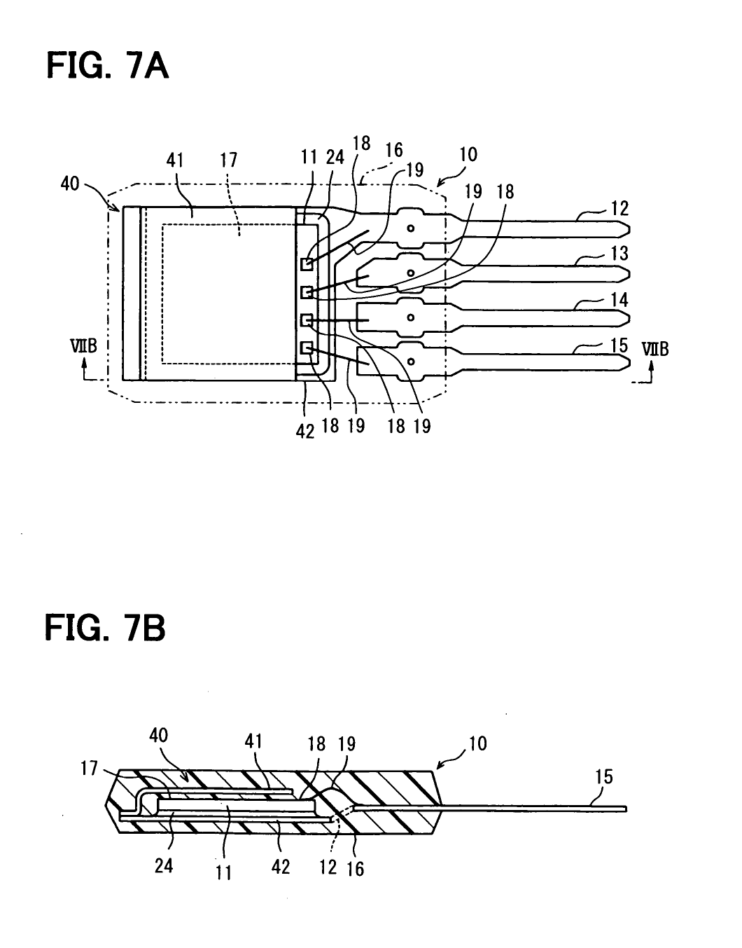

A sixth embodiment of the present invention is shown in FIGS. 7A and 7B. In this embodiment, a cover member 41 and a base member 42 are separately made from each other, as opposed to the structure in the foregoing embodiments. One end portion of the cover member 41 is bent toward the base member 42, as shown in FIG. 7B, and is connected to the base portion by welding. There is no spring-back action of the bent portion in this sixth embodiment. The lead portion 12 is integrally made with the base portion 42, and the IC-chip 11 mounted on the base portion 42 is disposed in the inner space between the cover portion 41 and the base portion 42.

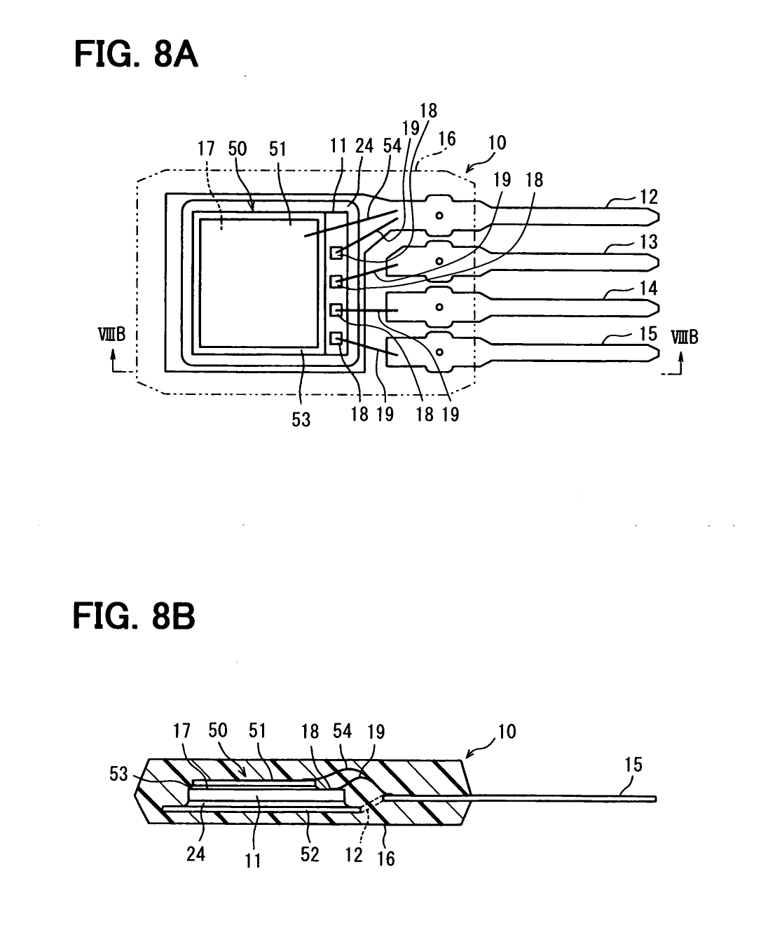

A seventh embodiment of the present invention is shown in FIGS. 8A and 8B. In this embodiment, a cover portion 51 and a base portion 52 are separately formed. The IC-chip 11 is mounted on the base portion 52 having the lead portion 12. The cover portion 51 is connected to the functioning surface 17 of the IC-chip 11 with adhesive 54. All the components including the leads 13-15 are connected together with the resin mold 16 in the same manner as in the foregoing embodiments. The cover portion 51 is electrically connected to the lead portion 12 with a bonding wire 54. It is not necessary to consider the spring-back action of the bending portion in this embodiment.

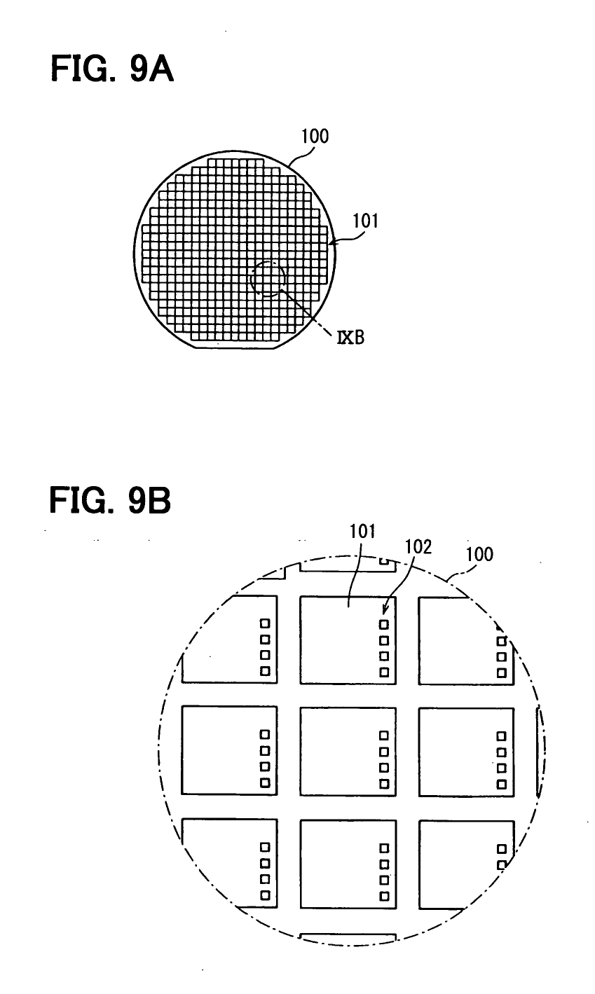

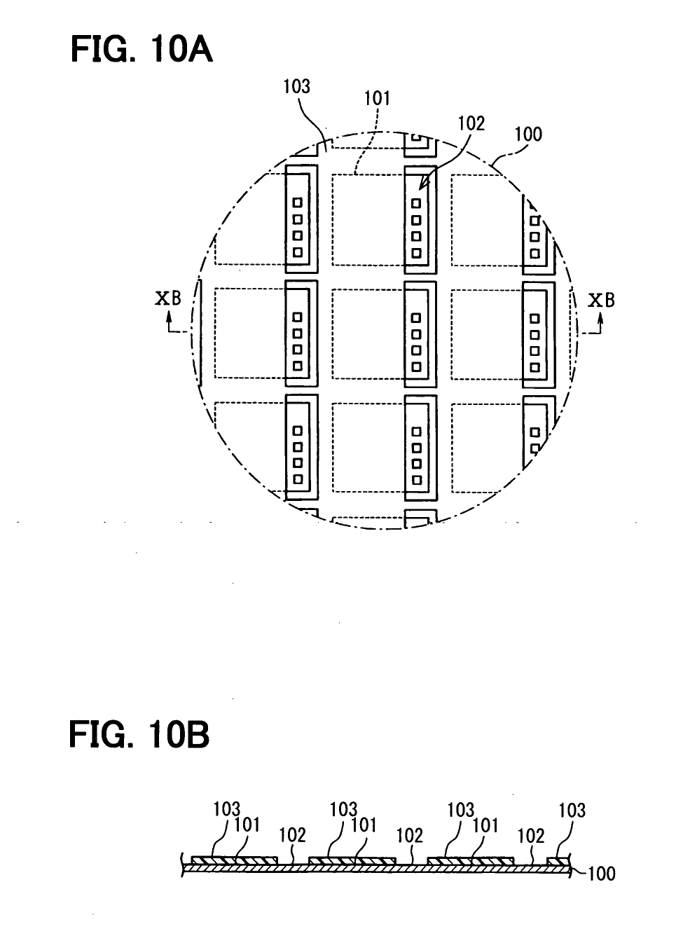

The semiconductor device 10 described above as the seventh embodiment of the present invention may be made in a process shown in FIGS. 9A-13B. A pattern 101 constituting the functioning surface 17 of plural IC-chips is formed on a silicon wafer 100. Bonding pads 102 are also formed together with the pattern 101, as shown in FIG. 9B. Adhesive 103 is coated on the surface of the silicon wafer 100 except for the area where the bonding pads 102 are formed, as shown in FIGS. 10A and 10B. The adhesive 103 is coated on the silicon wafer 100 by printing.

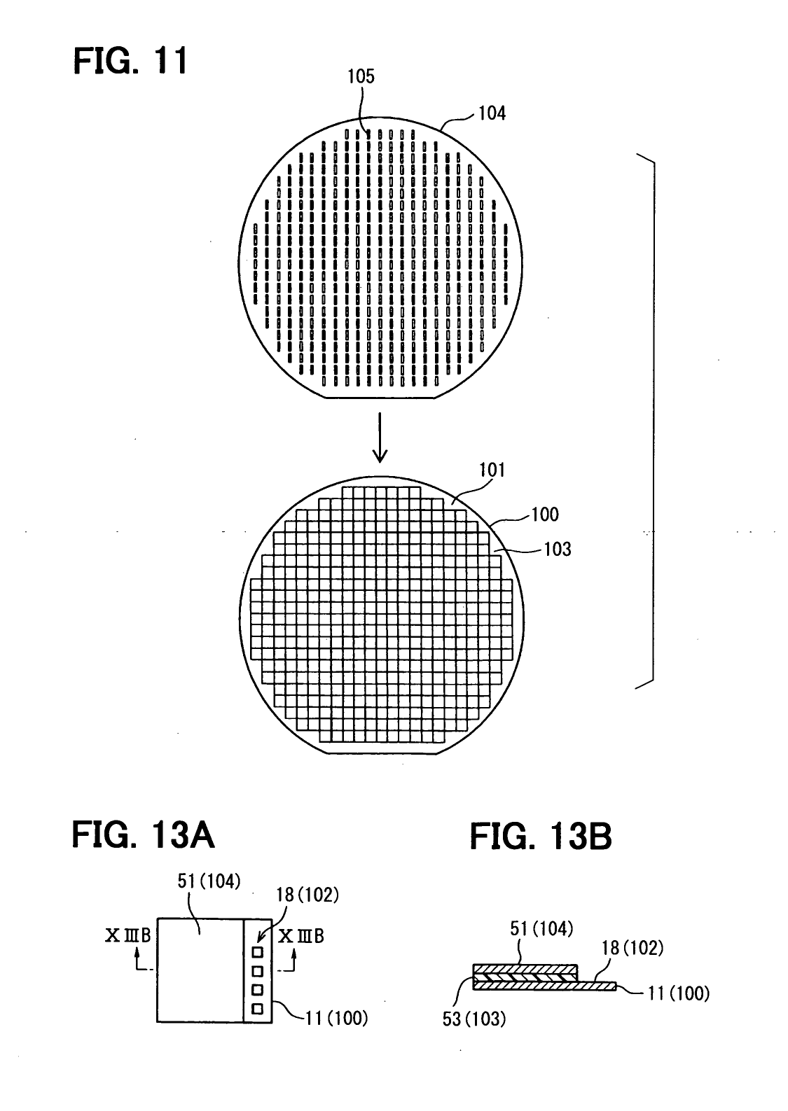

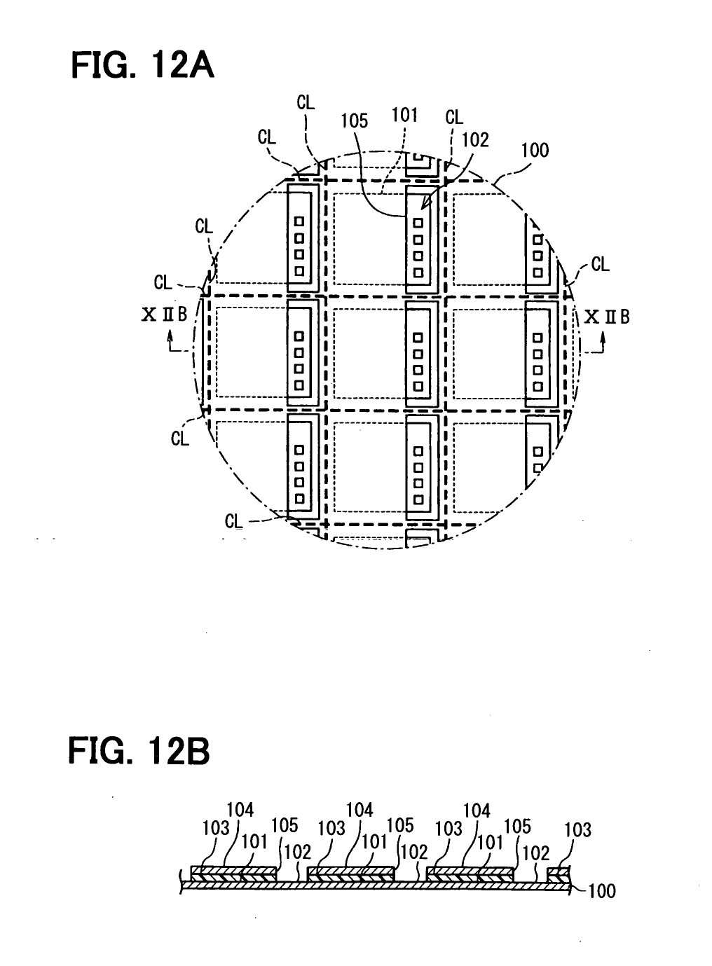

A thin metallic plate 104 forming the cover portion 51 is pasted on the silicon wafer 100, on which the adhesive 103 is coated, as shown in FIG. 11. The thin metallic plate 104 includes holes 105 that are formed at places corresponding to the bonding pads 102. As shown in FIGS. 12A and 12B, the bonding pads 102 are exposed through the holes 105 when the thin metallic plate 104 is pasted on the silicon wafer 100. Then, the individual IC-chips 11 are diced out from the silicon wafer 100 as shown in FIGS. 13A and 13B. Then, the IC-chip 11 is mounted on the base portion 52 having the lead portion 12 integrally formed with the base portion 52. Then, the cover portion 51 is electrically connected to the lead portion 12, and all of the components including the leads 13-15 are connected together by the resin mold 16.

In this manufacturing process, forming of the functioning surface 17 of the IC-chip 11, forming the bonding pads 18, coating of the adhesive 53 (103), and pasting the cover portion 51 are all performed in a series of steps for forming the IC-chip 11. Therefore, cover portion 51 is easily formed and correctly positioned with high accuracy on the IC-chip 11. The thin metallic plate 104 used in the process described above may be replaced with a metallic layer plated on the functioning surface 17.

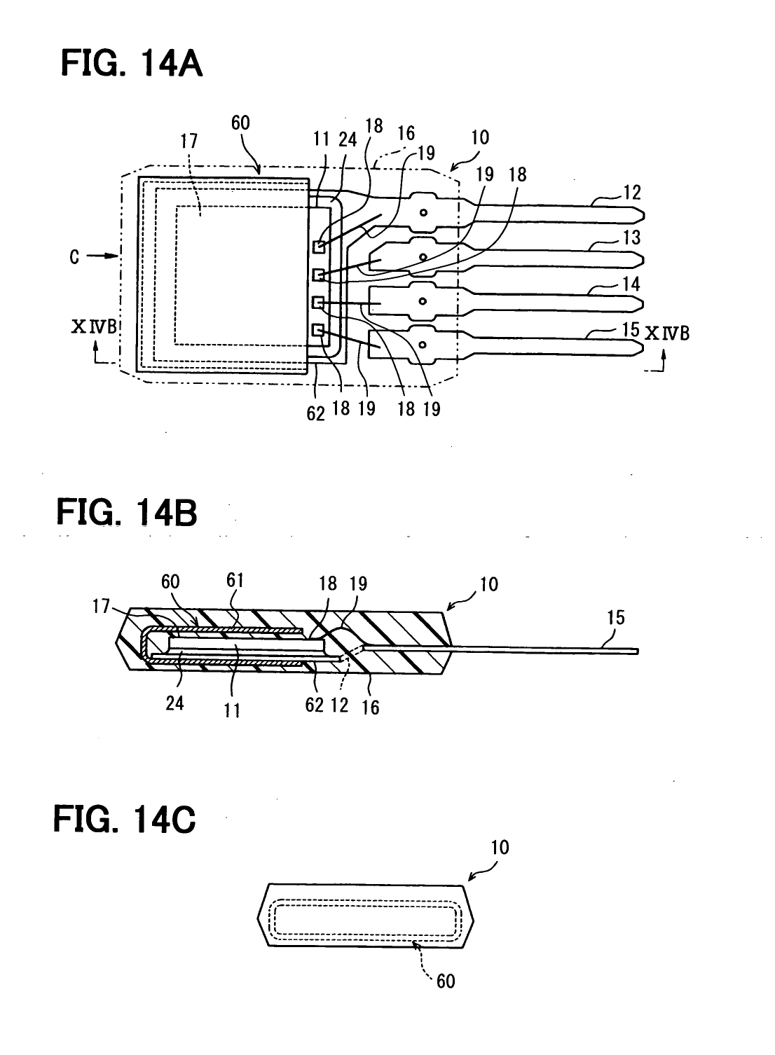

An eighth embodiment of the present invention is shown in FIGS. 14A-14C. In this embodiment, a cup-shaped conductor member 60 is used. The cup-shaped conductor member 60 includes a cover portion 61 covering the functioning surface 17 of the IC-chip 11 and a base portion 62 on which the IC-chip 11 is mounted. The cup-shaped conductor member 60 is made integrally with the lead portion 12. The cover portion 61 of the cup-shaped conductor member 60 may cover an entire area of the functioning surface 17. At least a part of the functioning surface 17 has to be covered with the cover portion 61 of the cup-shaped conductor member 60. Since the conductor member 60 is formed in a cup-shape, the functioning surface 17 of the IC-chip 11 is easily and surely covered with the conductor member, thereby avoiding malfunctions of the semiconductor device 10 due to noises or the electrostatic charges.

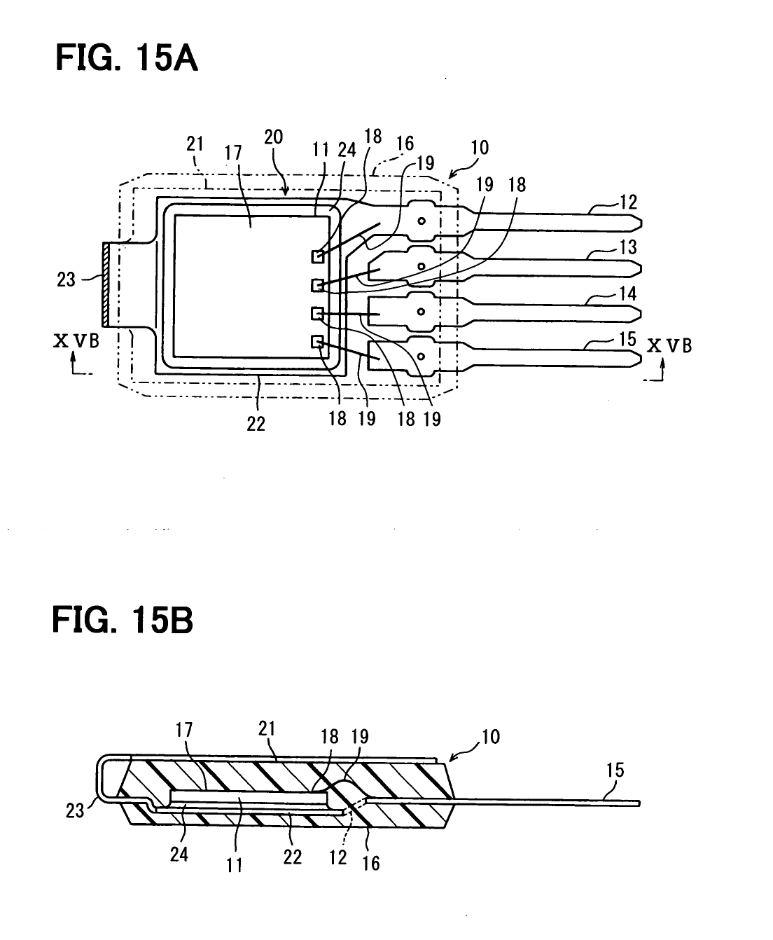

A ninth embodiment is shown in FIGS. 15A and 15B. This embodiment is similar to the first embodiment except that the cover portion 21 and the bent portion 23 are positioned outside of the resin mold 16. The conductor member 20 is formed integrally with the lead portion 12 in the same manner as in the first embodiment. The functioning surface 17 of the IC-chip 11 is covered with the resin mold 16, and an upper surface of the resin mold 16 is covered with the cover portion 21 of the conductor member 20. It is not necessary to place the cover portion 21 close to the functioning surface 17, but it can be placed outside of the resin mold 16. The IC-chip 11 is similarly protected from electromagnetic waves in this embodiment, too.

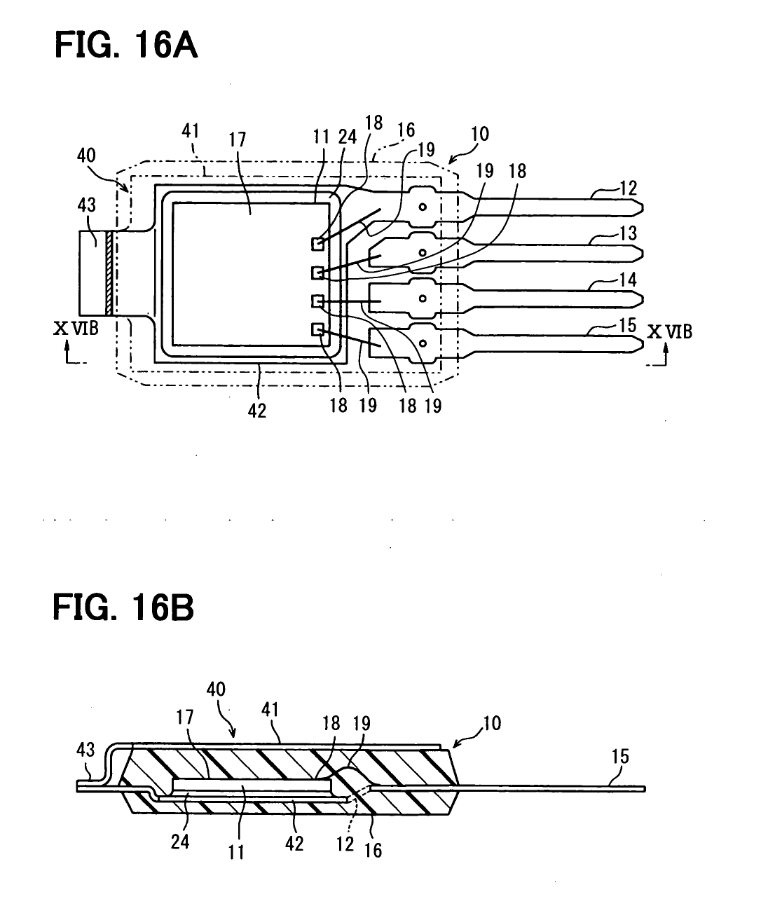

A tenth embodiment of the present invention is shown in FIGS. 16A and 16B. This embodiment is similar to the sixth embodiment except that the cover portion 41 and an end portion 43 are positioned outside of the resin mold 16. The conductor member 40 is composed of the cover member 41 having the end portion 43 and the base member 42 integrally formed with the lead portion 12. The end portion 43 disposed outside of the resin mold 16 is connected to the base portion 42 by welding. The IC-chip 11 is protected from the electromagnetic noises and electrostatic charges in the similar manner as in the foregoing embodiments.

While the present invention has been shown and described with reference to the foregoing preferred embodiments, it will be apparent to those skilled in the art that changes in form and detail may be made therein without departing from the scope of the invention as defined in the appended claims.

What is claimed is:

1. A semiconductor device comprising:
a conductor member having a base portion, a lead portion extending from the base portion, a cover portion, a bent portion connecting the cover portion and the base portion so that the cover portion and the base portion become substantially in parallel to each other, forming an inner space between the base portion and the cover portion, and a claw portion connecting the cover portion to the base portion at a position opposite to a position where the bent portion is made, all of the portions of the conductor member being integrally formed;
an IC-chip mounted on the base portion and disposed in the inner space so that a functioning surface of the IC-chip faces the cover portion;
leads electrically connected to the IC-chip; and
a resin mold integrally molding the conductor member, the IC-chip and the leads into a single unit, so that lead portion of the conductor member and the leads extend out of the resin mold.

2. The semiconductor device as in claim 1, wherein the claw portion extends from the cover portion toward the base portion and is connected to the base portion.

3. The semiconductor device as in claim 1, wherein the claw portion extends from the base portion and is connected to the cover portion.

4. The semiconductor device as in claim 1, wherein the claw portion extends from the cover portion toward the base portion and is welded to the base portion.

5. The semiconductor device as in claim 1, the bent portion includes at least one window to reduce a spring-back action of the bent portion when the bent portion is bent.

6. A semiconductor device comprising:
a conductor member composed of a base portion, a lead portion extending from the base portion and a cover portion, the cover portion being separately formed from the base portion, the cover portion and the base portion being positioned substantially in parallel to each other, forming an inner space between the base portion and the cover portion, the cover portion being connected to the base portion by welding at a position opposite to a position where the lead portion extends;
an IC-chip mounted on the base portion and disposed in the inner space so that a functioning surface of the IC-chip faces the cover portion;
leads electrically connected to the IC-chip; and
a resin mold integrally molding the conductor member, the IC-chip and the leads into a single unit, so that lead portion of the conductor member and the leads extend out of the resin mold.

7. A semiconductor device comprising:
a conductor member composed of a base portion, a lead portion extending from the base portion and a cover portion, the cover portion being separately formed from the base portion, the cover portion and the base portion being positioned substantially in parallel to each other, forming an inner space between the base portion and the cover portion, the cover portion being electrically connected to the lead portion through a bonding wire;
an IC-chip mounted on the base portion and disposed in the inner space so that a functioning surface of the IC-chip faces the cover portion;
leads electrically connected to the IC-chip; and
a resin mold integrally molding the conductor member, the IC-chip and the leads into a single unit, so that lead portion of the conductor member and the leads extend out of the resin mold.

8. A semiconductor device comprising:
a conductor member having a base portion, a lead portion extending from the base portion, a cover portion, a bent portion connecting the cover portion and the base portion so that the cover portion and the base portion become substantially in parallel to each other, forming an inner space between the base portion and the cover portion, the conductor member being integrally formed in a cup-shape;
an IC-chip mounted on the base portion and disposed in the inner space so that a functioning surface of the IC-chip faces the cover portion;
leads electrically connected to the IC-chip; and
a resin mold integrally molding the conductor member, the IC-chip and the leads into a single unit, so that lead portion of the conductor member and the leads extend out of the resin mold.

9. A semiconductor device comprising:
a conductor member having a base portion, a lead portion extending from the base portion, a cover portion, a bent portion connecting the cover portion and the base portion so that the cover portion and the base portion becomes substantially in parallel to each other, forming an inner space between the base portion and the cover portion, the conductor member being integrally formed into a U-shape;
an IC-chip mounted on the base portion and disposed in the inner space so that a functioning surface of the IC-chip faces the cover portion;
leads electrically connected to the IC-chip; and
a resin mold integrally molding the conductor member, the IC-chip and the leads into a single unit, so that lead portion of the conductor member and the leads extend out of the resin mold, and the bent portion and the cover portion are positioned outside of the resin mold.

10. The semiconductor device as in claim 6, wherein the cover portion and the portion where the cover portion is connected to the base portion by welding are positioned outside of the resin mold.

11. The semiconductor device as in claim 7, wherein the cover portion is pasted to the functioning surface of the IC-chip with adhesive.
